(19) United States
(12) Patent Application Publication
(10) Pub. No.: US 2014/0313843 A1
(43) Pub. Date: Oct. 23, 2014

(54) SEMICONDUCTOR INTEGRATED CIRCUIT AND CONTROL METHOD THEREFOR

(71) Applicant: NEC Corporation, Minato-ku, Tokyo (JP)

(72) Inventors: Ryusuke Nebashi, Tokyo (JP); Noboru Sakimura, Tokyo (JP); Yukihide Tsuji, Tokyo (JP); Ayuka Tada, Tokyo (JP)

(73) Assignee: NEC Corporation, Tokyo (JP)

(21) Appl. No.: 14/359,879

(22) PCT Filed: Nov. 20, 2012
(86) PCT No.: PCT/JP2012/080050

§ 371 Date: May 21, 2014

(30) Foreign Application Priority Data
Nov. 21, 2011 (JP) 2011-254028

(51) Int. Cl. G11C 5/14

(52) U.S. Cl. CPC G11C 5/148
USPC 365/227

(57) ABSTRACT

A semiconductor integrated circuit includes a plurality of first non-volatile registers including a retention circuit that retains volatile data and one or more non-volatile elements capable of retaining non-volatile data, and a second non-volatile register that retains a load enable bit that decides in which one of the plurality of first non-volatile registers data is loaded. The semiconductor integrated circuit also includes a non-volatile register control circuit that, when supply power is delivered from outside, loads to the retention circuit data retained by the non-volatile element(s) contained in the first non-volatile register specified by the load enable bit loaded from the second non-volatile register (FIG. 1).

### CROSS-REFERENCE TO RELATED APPLICATION

The present application claims priority rights based on JP Patent Application No. 2011-254028 filed on Nov. 21, 2011. The total contents of disclosure of the patent application of the senior filing date are to be incorporated by reference into the present application. This invention relates to a semiconductor integrated circuit and a control method therefor. More particularly, it relates to a semiconductor integrated circuit including a non-volatile register, and a control method therefor.

### TECHNICAL FIELD

### Background

These days, as the degree of integration of the semiconductor integrated circuit enhances, the leakage current in the transistors, used in the integrated circuit, is becoming of a problem. In particular, the leakage current in a state the integrated circuit is not in operation tends to increase such that power consumption ascribable to such leakage current is becoming non-negligible. Thus, there exists such a semiconductor integrated circuit having a low power consumption mode in which, when the semiconductor integrated circuit is not in operation, the power supply to the integrated circuit is turned off to decrease the leakage current.

However, if the power supply to the semiconductor integrated circuit is turned off, the value of a register that is to retain its inner state is erased. In this consideration, it is necessary that, in the semiconductor integrated circuit, data desired to be retained is retreated to an external storage device before the power supply is turned off.

Patent Literature [PTL] 1 shows a method which retains the state of component elements of a computer system, and the computer system having a function of re-booting after the power supply is completely turned off. In the computer system, disclosed in Patent Literature 1, the inner states of the system are read out using scan latches provided as system component elements. The inner states, thus read out, are retained in a retreat area, after which the power supply is turned off.

Patent Literature 2 shows a semiconductor device including a non-volatile memory and a latch circuit provided with a write circuit. In the semiconductor device, disclosed in Patent Literature 2, data in the latch circuit (volatile data) is written in the non-volatile memory before the power supply is turned off. Thus, in the semiconductor device of Patent Literature 2, making use of non-volatile memory cells, no complicated transfer operation is necessary, while data may be retreated at a fast speed.

### CITATION LIST

### Patent Literature

[PTL 1]: Japanese Patent Kokai Publication No. JP2002-182803A
[PTL 2]: Japanese Patent Kokai Publication No. JP2004-133969A

### SUMMARY

### Technical Problem

The disclosures of the above mentioned technical literatures are to be incorporated herein by reference. The following analysis is given in accordance with the present invention.

It should be noted that, if a memory device, provided aloof from the circuit that holds the inner states, is used, as in Patent Literature 1, there is produced time delay as well as power consumption accompanying the transfer of data. If, in particular, power supply is frequently turned onRmoff, time delay as well as power consumption accompanying the data transfer will be most problematical.

Additionally, the semiconductor device, disclosed in Patent Literature 2, has a drawback that, each time power supply switches, provided from one module to another, are turned onRmoff, it becomes necessary to perform unneeded writeRm load operations to retreat and restore data of all of non-volatile latches, contained in a module of interest, thus increasing power consumption. Moreover, the state that prevailed before power supply interruption occurred needs to be restored when the power supply is next turned on, which means a further drawback from the viewpoint of system flexibility.

There is thus a demand for such a semiconductor integrated circuit in which, in restoring the power supply of the integrated circuit, it is possible to suppress time and power consumption involved in recovering the once-retreated data.

### Solution to Problem

In one aspect of the present invention, there is provided a semiconductor integrated circuit, comprising a plurality of first non-volatile registers, including a retention circuit that retains volatile data and a non-volatile element(s) capable of retaining non-volatile data, a second non-volatile register that retains a load enable bit that decides in which one of the plurality of first non-volatile registers the data is to be loaded, and a non-volatile register control circuit that, when supply power is delivered from outside, causes the data retained by the non-volatile element(s) contained in the first non-volatile register identified by the load enable bit loaded from the second non-volatile register to be loaded into the retention in circuit.

In a second aspect of the present invention, there is provided a method for controlling a semiconductor integrated circuit including a plurality of first non-volatile registers, comprising a retention circuit that retains volatile data and a non-volatile element(s) capable of retaining the non-volatile data, in which the method comprises a first step of referring to a load enable bit that decides in which of the first non-volatile registers the data is to be loaded, and a second step of loading the data retained by the non-volatile elements contained in the first non-volatile register identified by the load enable bit into the retention circuit when supply power is delivered from outside.

### Advantageous Effects of Invention

In the respective aspects of the present invention, there are provided a semiconductor integrated circuit that may contribute to suppressing power consumption and time involved in restoring the once-retreated data when the power supply of the circuit is restored, and a control method therefor.

### BRIEF DESCRIPTION OF DRAWINGS

FIG. 1 is a block diagram showing the synopsis of an exemplary embodiment.

FIG. 2 is a block diagram showing an example interior configuration of a semiconductor integrated circuit 1 according to an exemplary embodiment 1.

FIG. 3 is a block diagram showing an example command format as used in the exemplary embodiment 1.

FIG. 4 is a circuit diagram showing an example configuration of a non-volatile flipflop 60.

FIG. 5 is a schematic cross-sectional view showing a domain wall displacement element that performs writing by exploiting the spin torque effect as non-volatile element as well as its neighbored portion.

FIG. 6 is a schematic view showing example connections of non-volatile registers R1 to Rm, contained in a semiconductor integrated circuit 1, and a non-volatile register control circuit 30 as a control circuit therefor.

FIG. 7 is a diagrammatic view showing operation waveforms for a case where a command code is a write command for writing into the non-volatile elements.

FIG. 8 is a diagrammatic view showing operation waveforms for a case where a command code is a load command for loading from the non-volatile elements.

FIG. 9 is a schematic view showing an example interior configuration of a semiconductor integrated circuit 2 according to an exemplary embodiment 2.

FIG. 10 is a schematic view showing example connections of non-volatile registers R1 to Rm to a non-volatile register control circuit 30a, a control circuit for the non-volatile registers. All of these are contained in a semiconductor integrated circuit 2.

FIG. 11 is a flowchart showing example operations at the time of system booting of the semiconductor integrated circuit 3 according to an exemplary embodiment 3.

FIG. 12 is a flowchart showing example operations at the time of system booting of a semiconductor integrated circuit 4 according to an exemplary embodiment 4.

FIG. 13 is a schematic view showing an example circuit configuration of a non-volatile flipflop 60a according to an exemplary embodiment 5.

FIG. 14 is a schematic view showing example connections of non-volatile registers R1 to Rm to a non-volatile register control circuit 30b, a control circuit for the non-volatile registers. All of these are contained in a semiconductor integrated circuit 5.

### DESCRIPTION OF EMBODIMENTS

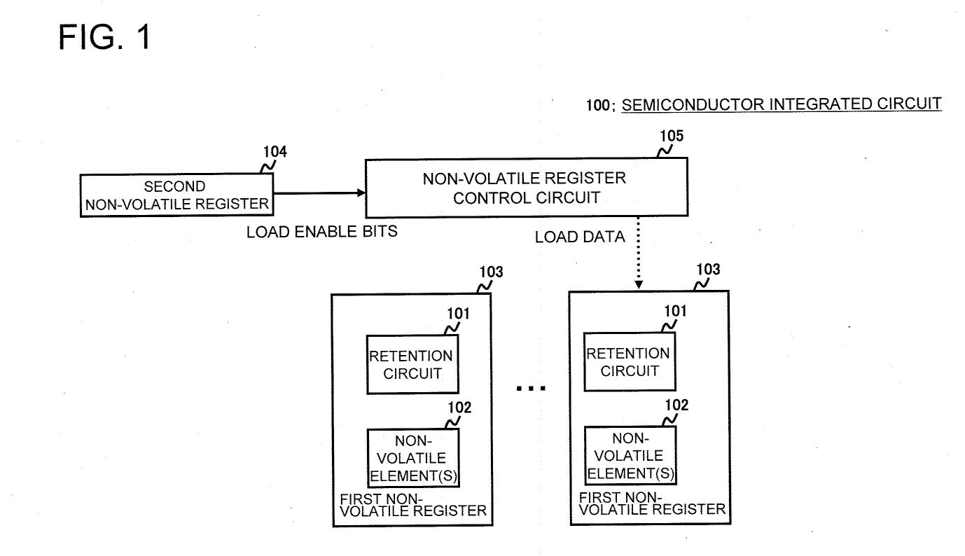

Initially, the synopsis of an exemplary embodiment will be explained with reference to FIG. 1. It is noted that symbols for reference to the drawings are appended to respective components merely as examples to assist in understanding, and the invention is not to be restricted to the particular mode illustrated.

Since the memory elements and the logic elements are arranged separately, as described above, data transfer delay as well as power consumption of the interconnects or the circuits on which data is transferred will increase at the time of restoration from the power supply off state. By this reason, such a semiconductor integrated circuit in which it is possible to suppress power consumption as well as time involved in restoring the once-retreated data on recovery of the power supply of the semiconductor integrated circuit, as well as a control method therefore, has been a desideratum.

Thus, a semiconductor integrated circuit 100, shown in FIG. 1, is provided as an example. The semiconductor integrated circuit 100, shown in FIG. 1, comprises a plurality of first non-volatile registers 103, including a retention circuit 101 that retains volatile data and a non-volatile element(s) 102 capable of retaining non-volatile data. The semiconductor integrated circuit also includes a second non-volatile register 104 that retains a load enable bit that decides in which one of the plurality of first non-volatile registers 103 the data is to be loaded, and a non-volatile register control circuit 105 that, when supply power is delivered from outside, causes the data retained by the non-volatile element(s) 102 contained in the first non-volatile register 103 identified by the load enable bit loaded from the second non-volatile register 104 to be loaded into the retention circuit 101.

Each of the first non-volatile registers 103, contained in the semiconductor integrated circuit 100, is made up of the retention circuit 101, as logic element, and the non-volatile element(s) 102, as memory element(s), formed as one with the retention circuit. Since the logic element and the memory element(s) are thus formed as one with each other, it is possible to prevent delay in data transfer before the power supply is restored from its off state, and hence to reduce power consumption otherwise caused in the interconnects or circuits used for transferring the data. Moreover, since the number of the non-volatile elements 102 from which data is to be loaded is identified by the load enable bit(s) and hence may be reduced, the power consumption involved in data restoration may be decreased, while the targeted post-restoration state may be achieved more promptly.

Furthermore, the following modes are also possible.

[Mode 1] The semiconductor integrated circuit according to the first aspect as stated above.
[Mode 2] Preferably, the plural first non-volatile registers are divided into a plurality of groups, each group being either correlated or not correlated to the load enable bit. Preferably, the non-volatile register control circuit causes the data retained by the non-volatile element(s) contained in the first non-volatile register belonging to the group specified by the load enable bit to be loaded into the retention circuit.
[Mode 3] In the above mentioned semiconductor integrated circuit, whether or not data retained by the non-volatile element(s) contained in the first non-volatile register belonging to the group not correlated to the load enable bit is to be loaded into the retention circuit preferably is to obey a predetermined rule.
[Mode 4] Preferably, the above mentioned semiconductor integrated circuit further comprises a command decoder that decodes a command for a central processing unit and a memory that retains the command. An address is donated to each of the plural first non-volatile registers, which are divided into a plurality of groups. The command includes an address bit that specifies an address corresponding to the plural first non-volatile registers and a load bit that instructs loading data from the plural first non-volatile registers. Depending on the result of the command decoder decoding the command read out from the memory, the non-volatile register control circuit preferably causes loading of data of the first non-volatile registers, which belong to the same group of the first non-volatile registers as that of the first non-volatile register identified by the address bit, and for which the corresponding load bit has been activated. [Mode 5] Preferably, the plural first non-volatile registers are divided into a plurality of groups. The semiconductor integrated circuit comprises a power supply control circuit capable of delivering a plurality of load signals that decide which of the groups the plural first non-volatile registers belong to is to be activated. The non-volatile register control circuit loads data of the first non-volatile registers which belong to the group corresponding to a load signal delivered by the power supply control circuit and for which the corresponding load enable bit has been activated.
[Mode 6] Preferably, the non-volatile register control circuit performs, when supply power is delivered from outside, either a system boot not including the operation of loading into the retention circuit the data retained by the non-volatile elements included in the first non-volatile register, or a system boot including the operation of loading into the retention circuit the data retained by the non-volatile elements included in the first non-volatile register, based on a loading-related branch flag.
[Mode 7] Preferably, data relevant to a program counter is retained by one of the plural first non-volatile registers. When supply power is delivered from outside, the non-volatile register control circuit causes the data to be loaded from the non-volatile elements contained in the non-volatile register retaining data relevant to a program counter into the retention circuit. The non-volatile register control circuit performs, based on the value of the program counter, either a system boot not including the operation of loading into the retention circuit the data retained by the non-volatile elements included in the first non-volatile register or a system boot including the operation of loading into the retention circuit the data retained by the non-volatile elements included in the first non-volatile register.
[Mode 8] Preferably, the plural non-volatile registers receive first and second write signals and one input data. In case of activation of the first write signal, the non-volatile registers allow the data of the retention circuit to be written into the non-volatile elements. In case of activation of the second write signal, the non-volatile registers allow the input data to be written in the non-volatile elements without changing data retained by the retention circuits.
[Mode 9] The method for controlling a semiconductor integrated circuit according to the second aspect as stated above.
[Mode 10] Preferably, the second step includes either a step of booting a system as the data retained by the non-volatile elements contained in the first non-volatile register is not loaded into the retention circuit, or a step of booting the system as the data retained by the non-volatile elements contained in the first non-volatile register is loaded into the retention circuit, based on a loading-related branch flag, when the supply power is delivered from outside.
[Mode 11] Preferably, the above mentioned second step includes a step of loading the value of the program counter into the retention circuit contained in the first non-volatile register and, depending on the value of the program counter, either a step of booting a system as the data retained by the non-volatile elements contained in the non-volatile register is not loaded into the retention circuit or a step of booting the system as the data retained by the non-volatile element contained in the non-volatile register is loaded into the retention circuit, when the supply power is delivered from outside.

More concrete exemplary embodiments of the present invention will now be explained in detail with reference to the drawings.

### Exemplary Embodiment 1

A exemplary embodiment 1 will now be explained in detail with reference to the drawings.

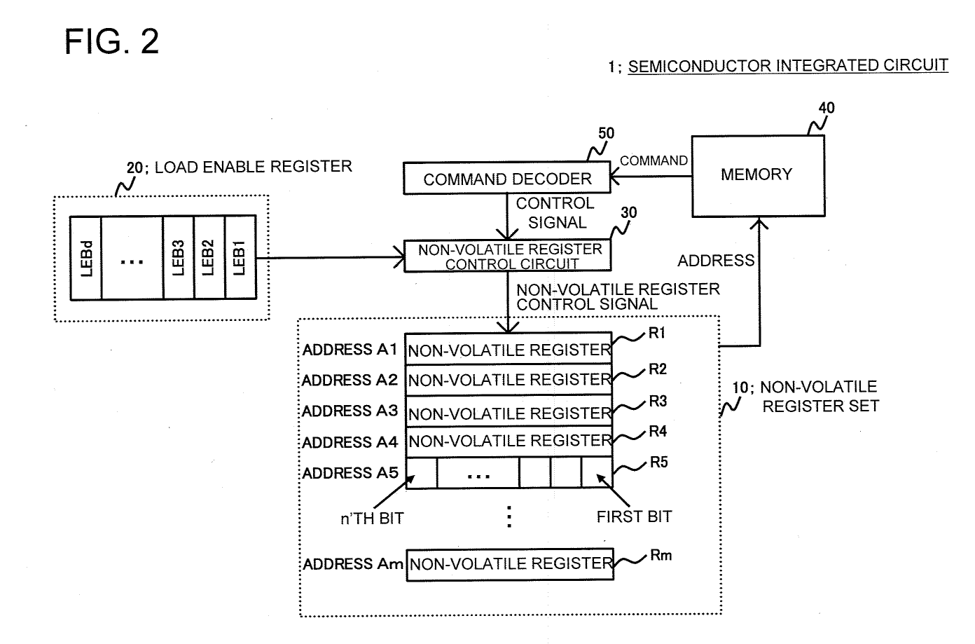

FIG. 2 depicts an example interior configuration of a semiconductor integrated circuit 1 according to the exemplary embodiment 1. For simplicity of explanation, there is shown in FIG. 2 a module of the semiconductor integrated circuit involved in the restoration from the state of power supply interruption.

The semiconductor integrated circuit 1 is made up by a non-volatile register set 10, a load enable register 20, a non-volatile register control circuit 30, a memory 40 and a command decoder 50.

The non-volatile register set 10 includes a plurality of non-volatile registers R1 to Rm, where m denotes an integer not smaller than 2, hereinafter the same. Each non-volatile register is able to retain the n-bit information, where n denotes an integer not smaller than 2, hereinafter the same. Each non-volatile register is made up of a plurality of flipflops each retaining the 1-bit information. That is, each non-volatile register is able to retain the information of n bits, and hence is made up of n non-volatile flipflops. It is noted that the number of bits n of the non-volatile registers may vary from one non-volatile register to another. However, in the semiconductor integrated circuit 1 of the subject exemplary embodiment, the value of n is assumed to be the same from one non-volatile register to another.

Each non-volatile flipflop includes a retention circuit retaining volatile data and a non-volatile element(s) retaining non-volatile data. Details of the retention circuit and the non-volatile element(s) will be explained subsequently.

The non-volatile flipflop has a function to transfer data between the retention circuit and the non-volatile element(s). In the present description, transferring data of the retention circuit to the non-volatile element(s) is defined as write into the non-volatile element(s), while transferring data of the non-volatile element(s) to the retention circuit is defined as loading from the non-volatile element(s).

As stated above, the semiconductor integrated circuit 1 includes the m non-volatile registers, to which addresses A1 through to Am are donated. Examples of the non-volatile registers may include a program counter PC, a stack point SP, a status register SR, a general-purpose register and a register used in a peripheral module. The values retained by these non-volatile registers are expressive of inner states of the semiconductor integrated circuit 1. Therefore, if, after retreating the values of the retention circuit to the non-volatile element(s), the power supply to the semiconductor integrated circuit 1 is turned off, and the data are restored when the power supply is again turned on, it is possible to restore the state of the semiconductor integrated circuit 1 to that which prevailed before the power supply was turned off, that is, before operation interruption.

The load enable register 20 may retain a plurality of bits. Here, the load enable register 20 is assumed to be retaining d bits, where d denotes an integer not smaller than 2, hereinafter the same. Note that the bits included in the load enable register 20 are labeled as load enable bits LEB1 through to LEBd, and will now be detailed.

The load enable bits LEB are used on the occasion of deciding in which one of the plural non-volatile registers R1 to Rm data are to be loaded. The relationship of correspondence between the load enable bits LEB and the non-volatile registers is as follows: The m non-volatile registers, contained in the non-volatile register set 10, may be divided into q groups G1 to Gq, where q denotes an integer not smaller than 2, hereinafter the same. Each of the groups G is either correlated to one of the plural load enable bits LEB1 through to LEBd, or correlated to none of the load enable bits.

The method for using the load enable bits LEB will now be summarized.

The load enable bits LEB are loaded into the non-volatile register control circuit 30 immediately after supply power is delivered to the semiconductor integrated circuit 1. That is, the load enable bits LEB are loaded into the non-volatile register control circuit before data loading occurs in the non-volatile registers R1 to Rm. Thus, the non-volatile register control circuit 30 is able to refer to the load enable bits LEB in advance of the non-volatile registers R1 to Rm.

In performing the loading in the non-volatile registers R1 to Rm, the non-volatile register control circuit 30 names or specifies one of the non-volatile registers R1 to Rm, and refers to the load enable bit LEB corresponding to the group the so specified non-volatile register belongs to. If the value of the load enable bit LEB, thus referred to, is ‘1’, indicating an activated state, data of the non-volatile elements is loaded into the retention circuit in the specified non-volatile register. If the value of the load enable bit LEB referred to is ‘0’, the data of the non-volatile elements of the specified non-volatile register is not loaded into the retention circuit. For a case where there is no corresponding load enable bit, whether or not data of the non-volatile elements of the non-volatile register specified is to be loaded into the retention circuit is fixedly pre-set in the non-volatile register control circuit 30. The method for naming (specifying) the non-volatile registers R1 to Rm by the non-volatile register control circuit 30 will be considered subsequently.

The semiconductor integrated circuit 1 according to the subject exemplary embodiment includes a set of commands. The command set includes a non-volatile register control command which enables control of the non-volatile registers R1 to Rm.

Next, the sequence from command readout until control of the non-volatile registers will be summarized.

Initially, a central processing unit of the semiconductor integrated circuit 1, not shown in FIG. 2, reads out a command stored in the address from the memory 40 in accordance with an address as specified by the program counter PC. The command read out is sent to the command decoder 50 where it is decoded. If the command code is a command to write into the non-volatile elements, the non-volatile register control circuit 30 causes data retained by the retention circuit of the non-volatile register specified to be written into the non-volatile elements. If, on the other hand, the command code is a load command for the non-volatile elements, the non-volatile register control circuit 30 causes data of the non-volatile elements of the non-volatile register specified to be loaded into the retention circuit.

Next, details of the control command for the non-volatile register will be explained.

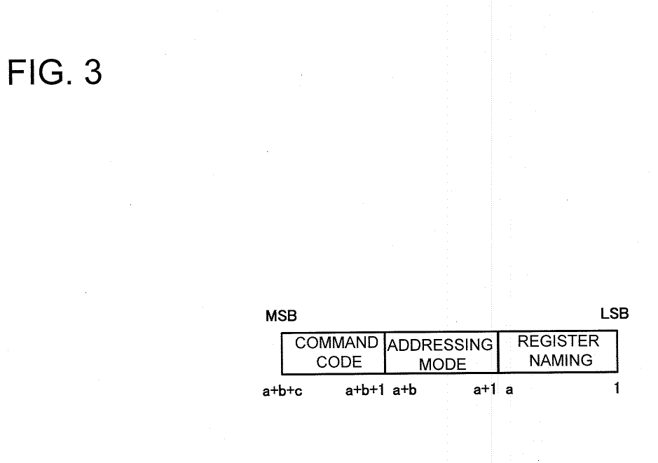

It is assumed that the semiconductor integrated circuit 1 of the subject exemplary embodiment uses a single-operand command style. FIG. 3 shows an example command style as used in the semiconductor integrated circuit 1. The command shown in FIG. 3 has a bit length of (a+b+c), where a to c denote integers, hereinafter the same. The first to the ath bits are used for specifying the register, while the (a+1)th to the (a+b)th bits are used for specifying an addressing mode and the (a+b+1)th to the (a+b+c)th bits for specifying a command code.

By adding the control command for the non-volatile register to the command code, it becomes possible to control the non-volatile register without altering a pre-existing architecture. For example, in performing writing in the non-volatile register R4, bearing the register number 4, the register specifying bit is set for specifying the register number 4. The addressing mode is set as in setting the customarily provided register actuating mode. A newly added write command for the non-volatile register is set in the command code. As for the addressing mode, such a mode that is different from the customarily provided mode may also be used.

Moreover, the m non-volatile registers of from the address A1 down to the address Am may be divided into t groups, t being an integer not smaller than 2, hereinafter the same. Thus, should a certain address be specified, the non-volatile registers of the group to which belong the non-volatile registers bearing such address may be controlled simultaneously. For example, it is now assumed that each of the non-volatile registers R1 to Rm has one load enable bit LEB, and loading is to be performed just in the non-volatile registers, out of the total of the non-volatile registers, having the values of the load enable bits LEB equal to ‘1’. Then, the number of the groups of the non-volatile registers in which data loading is to be made is 1, the number of the load enable bits LEB is m and the number of the groups q correlated to the load enable bits LEB is also m. The bits for identifying or specifying the registers may not be taken into account. The addressing mode may be set to the mode for actuating the non-volatile registers, and the command code may be set.

If the plural non-volatile registers R1 to Rm are operated in this manner simultaneously, the control time for the non-volatile registers may be reduced. In the semiconductor device of Patent Literature 2, in which loading is made in the total of the registers in a given module, it becomes necessary to perform the loading even from the non-volatile elements, the loading from which is unneeded, resulting in wasteful power consumption. However, if limitations are imposed on the non-volatile registers in which loading is to be made, with the use of the load enable bits LEB, it becomes possible to reduce the power consumption involved in the data recovery as the overhead needed for the data recovery is suppressed from increasing. It should be noted that, while it has been indicated above that the single operand command style can be used as the control command for the non-volatile registers, the invention is not to be restricted to this particular mode.

The non-volatile flipflop that makes up the non-volatile register will now be discussed.

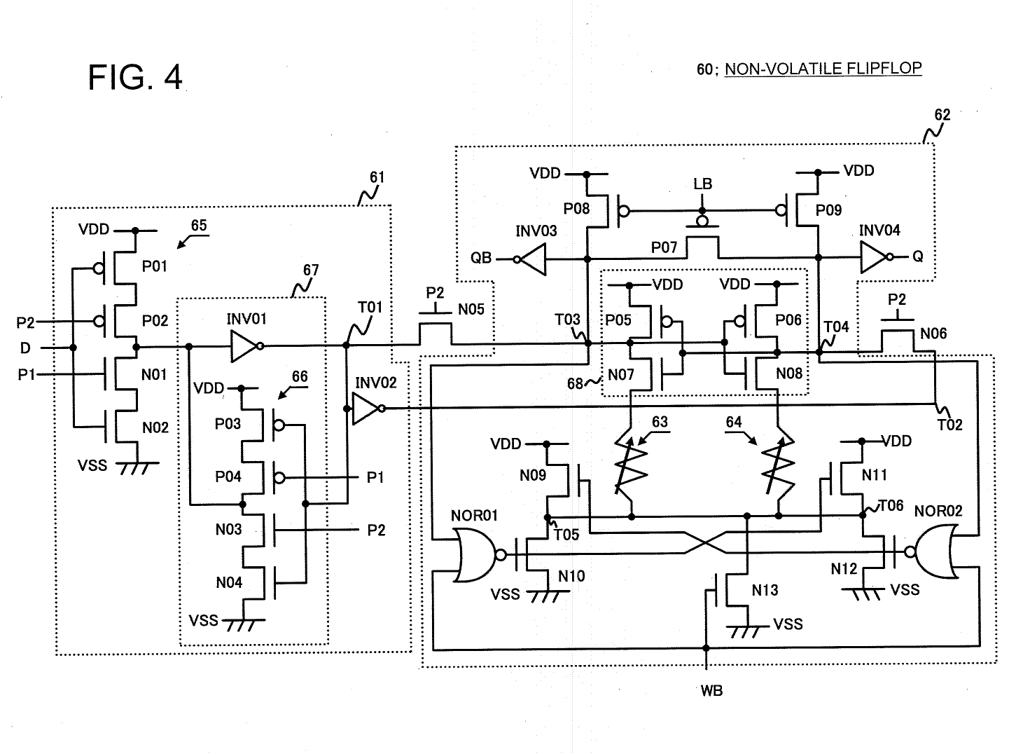

FIG. 4 shows an example circuit configuration of a non-volatile flipflop 60, which non-volatile flipflop 60 includes a master latch 61 and a slave latch 62. The slave latch, in turn, includes non-volatile elements 63, 64.

The master latch 61 and the slave latch 62 are able to retain volatile data. In the non-volatile flipflop 60, data may be exchanged between the slave latch 62 and the non-volatile elements 63, 64. More specifically, the non-volatile flipflop 60 has the function of writing data of a retention circuit included in the slave latch 62 into the non-volatile elements 63, 64 and the function of loading the data from the non-volatile elements 63, 64 into the slave latch 62.

The master latch 61 is made up of clocked inverters 65, 66 and inverters INV01, INV02. The clocked inverter 65 is made up of N-channel MOS transistors N01, N02 and P-channel MOS transistors P01, P02, while the clocked inverter 66 is made up of N-channel MOS transistors N03, N04 and P-channel MOS transistors P03, P04. Also, a retention circuit 67 is made up of the inverter INV01 and the clocked inverter 66 comprised of the N-channel MOS transistors N03, N04 and the P-channel MOS transistors P03, P04.

Input data D is entered via the clocked inverter 65 to the master latch 61 so as to be latched by the retention circuit 67. Data entered to the master latch 61 is retained at a node T01, while data inverted by the inverter INV02 is retained at a node T02. The data retained at the nodes T01, T02 are entered via N-channel MOS transistors N05, N06 to nodes T03, T04 of the slave latch 62.

The slave latch 62 includes a retention circuit 68 and a write transistor(s). The retention circuit 68 is made up of N-channel MOS transistors N07, N08 and P-channel MOS transistors P05, P06, while the write transistor(s) is made up of N-channel MOS transistors N09 to N12. The slave latch also includes NOR circuits NOR1, NOR2, an N-channel MOS transistor N13, P-channel MOS transistors P07 to P09, output inverters INV03, INV04 and the non-volatile elements 63, 64.

The N-channel MOS transistor N13 grounds the N-channel MOS transistors N07, N08 except during data write time. The P-channel MOS transistors P07 to P09 are used as pre-charging transistors.

The non-volatile element 63 has one end connected to the source of the N-channel MOS transistor N07, while having the other end connected common to the drains of the N-channel MOS transistors N09 to N012. The non-volatile element 64 has one end connected to the source of the N-channel MOS transistor N08, while having the other end connected common to the drains of the N-channel MOS transistors N09 to N012. Complementary data latched by the N-channel MOS transistors N07, N08 and the P-channel MOS transistors P05, P06 are entered to the NOR circuits NOR1, NOR2.

A write signal WB is entered to the N-channel MOS transistor N13 and to the NOR circuits NOR1, NOR2. A load signal LB is entered to the gates of the P-channel MOS transistors P07 to P09. An output signal from the inverter INV04 is labeled as data output Q, an output signal from the inverter INV03 is labeled as data output QB. A clock CLK is inverted by an inverter, not shown, to a clock P1 which is delivered to the clocked inverters 65, 66. The clock P1 is further inverted by another inverter, not shown, to a clock P2, which is also delivered to the clocked inverters 65, 66.

Note that the non-volatile flipflop 60 includes, in addition to the function proper to a flipflop, the following functions: First, the non-volatile flipflop includes a function to write data electrically stored in the slave latch 62 into the non-volatile elements 63, 64. Second, the non-volatile flipflop includes a function to read out data stored in the non-volatile elements 63, 64 to store the data in the slave latch 62.

For use as the non-volatile elements 63, 64, an MTJ (Magnetic Tunnel Junction) element, a ferromagnetic tunnel junction device exploiting the magnetoresistive effect, may be contemplated. The MTJ element includes a ferromagnetic layer (free layer), whose direction of magnetization is varied, another ferromagnetic layer (fixed layer), whose direction of magnetization is fixed, and an insulation layer formed between the free and fixed layers.

If now the current is caused to flow through the MTJ element in a direction perpendicular to its film surface, the resistance value of the MTJ element is varied in accordance with the directions of magnetization of the free and fixed layers. In case the direction of magnetization of the free layer is parallel to that of the fixed layer, the resistance value becomes lower. On the other hand, in case the direction of magnetization of the free layer is antiparallel to that of the fixed layer, the resistance value becomes higher. In the MTJ element, such property is exploited to correlate logical data to the resistance values or to the direction of magnetization of the free layer. Thus, the low resistance state is correlated to the logical value 0, the high resistance state to the logical value 1, as an example. For writing in the MTJ element, there are known two methods, namely a magnetic field write method that uses a current magnetic field to control the direction of magnetization of the free layer, and a spin torque write method that uses the spin torque effect to control the direction of magnetization of the free layer.

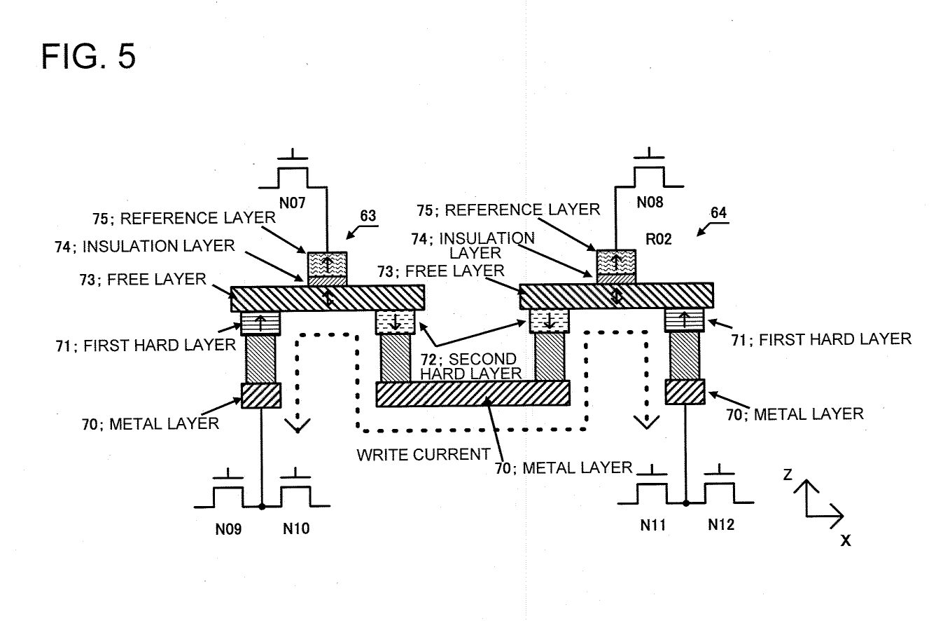

FIG. 5 shows, in a cross-section, a domain wall displacement element as well as its neighbored portion. The domain wall displacement element, as a non-volatile element, performs writing using the spin torque effect. It is noted that transistors composing the non-volatile elements 63, 64 are indicated by symbols for ease in understanding.

The non-volatile elements 63, 64 are made up of a metal layer 70, first hard layers 71, second hard layers 72, free layers 73, insulation layers 74 and reference layers 75, stacked together in this order, looking from a semiconductor substrate as reference.

As for connections for the non-volatile element 63, the reference layer 75 is connected to the N-channel MOS transistors N07, and the first hard layer 71 to the N-channel MOS transistors N09, N10. The second hard layer 72 is connected via the first hard layer 71 of the non-volatile element 64 to the N-channel MOS transistors N11, N12. For the free layer 73 and for the first and second hard layers 71, 72, magnetic thin films having perpendicular magnetic anisotropy may, for example, be used. The directions of magnetization of the first and second hard layers 71, 72 are fixed so as to be reversed to each other. The free layer 73 may have its magnetization controlled in the up-and-down direction, as indicated by Z in FIG. 5, in accordance with the direction of the spin polarized current. In more concrete terms, if the current is caused to flow from the first hard layer 71 to the second hard layer 72, polarized electrons will flow in the reverse direction, such that the free layer 73 has its direction of magnetization aligned with that of the second hard layer 72. If conversely the current is caused to flow from the second hard layer 72 to the first hard layer 71, the free layer has its direction of magnetization aligned with that of the first hard layer 71.

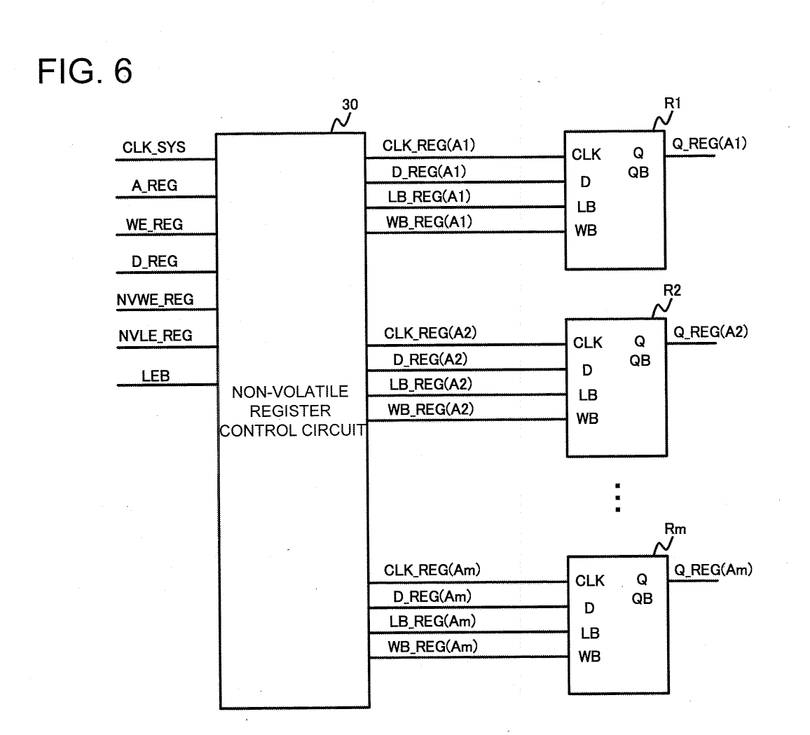

FIG. 6 shows example connections of the non-volatile registers R1 to Rm to the non-volatile register control circuit 30, all provided in the semiconductor integrated circuit 1. The non-volatile register control circuit is a control circuit for the non-volatile registers.

In the semiconductor integrated circuit 1 of the subject exemplary embodiment 1, an address is donated to each of the n non-volatile registers. For example, an address is donated in terms of a 16-bit word (n=16) or an 8-bit word (n=8) as units. There are m addresses of the non-volatile registers, namely addresses A1 to Am.

In the semiconductor integrated circuit 1, it is assumed that, in case one address is specified, the n non-volatile registers corresponding to the so specified address may be controlled at the same time. Or, in case one address is specified, a certain plurality of the non-volatile registers, included in an address space of the one address, may be controlled at the same time.

The non-volatile register control circuit 30 receives a system clock CLK_SYS, an address of one register A_REG, a volatile data write signal for the register WE_REG, input data D_REG to the register, a write signal NVWE_REG into the non-volatile elements 63, 64, a load signal NVLE_REG from the non-volatile elements 63, 64 and a load enable bit LEB. It is from the load enable register 20 and the command decoder 50 that these control signals are delivered.

The non-volatile register control circuit 30 is responsive to the control signals received to output a non-volatile register control signal to each of the non-volatile registers. For example, the non-volatile register control signals, delivered to the non-volatile register R1 corresponding to the address A1, may be comprised of a clock CLK_REG (A1), an input data D_REG(A1), a load signal LB_REG (A1) and a write signal WB_REG(A1). The non-volatile register R1 that has received the control signals outputs a data output Q_REG(A1). Similar operations are performed by the non-volatile registers R2 to Rm corresponding respectively to the addresses A2 to Am. Note that, in FIG. 6, one of the non-volatile flipflops, such as a non-volatile flipflop for the n'th bit, among the non-volatile flipflops in the non-volatile register, is shown as being representative.

Referring to FIG. 4, the write operation in the non-volatile register will now be summarized.

At the time of the write operation in the semiconductor integrated circuit 1, the write signal WB is set to an L level. At such time, the write data into the non-volatile elements coincides with a data output Q of the slave latch 62. In case the data output Q is ‘0’, the N-channel MOS transistors N10, N11 are on, while the N-channel MOS transistors N09, N12 are off. At this time, the write current flows from the node T06 to the node T05. This sets the non-volatile element 63 and the non-volatile element 64 to the low resistance state and to the high resistance state, respectively, whereby the data ‘0’ corresponding to the data output Q is stored in the non-volatile elements 63, 64.

On the other hand, in case the data output Q is ‘1’, the N-channel MOS transistors N010, N11 are off, while the N-channel MOS transistors N09, N12 are on. At this time, the write current flows from the node T05 to the node T06. This sets the non-volatile element 63 and the non-volatile element 64 to the high resistance state and to the low resistance state, respectively, whereby the data ‘1’ corresponding to the data output Q is stored in the non-volatile elements.

Next, referring to FIG. 4, the operation of loading in the non-volatile register will be summarized.

At the time of loading by the semiconductor integrated circuit 1, the load signal LB is set to an L level. The clock CLK is also in an L level. The P-channel MOS transistors P07 to P09 are then turned on, so that the nodes T03, T04 are at an H level. As a result, the readout current flows in the non-volatile element 63 via the N-channel MOS transistor N07. In addition, the readout current flows in the non-volatile element 64 via the N-channel MOS transistor N08. There is generated a minor potential difference across the nodes T03 and T04 in response to the difference between the values of the readout currents.

When the load signal LB is set to the H level, the potential difference is amplified. If the data retained in the non-volatile elements 63, 64 is ‘0’, the non-volatile element 63 is in the low resistance state, while the non-volatile element 64 is in the high resistance state. Hence, the node T03 is in the L level, while the node T04 is in the H level. As a result, the data output Q is ‘0’ in responsive to the data of the non-volatile elements. On the other hand, if the data retained in the non-volatile elements 63, 64 is ‘1’, the non-volatile element 63 is in the high resistance state, while the non-volatile element 64 is in the low resistance state. Hence, the node T03 is in the H level, while the node T04 is in the L level. As a result, the data output Q is ‘1’ in responsive to the data of the non-volatile elements.

Next, such a case in which, in the semiconductor integrated circuit 1, the command code is a write command for the non-volatile elements will be considered in detail.

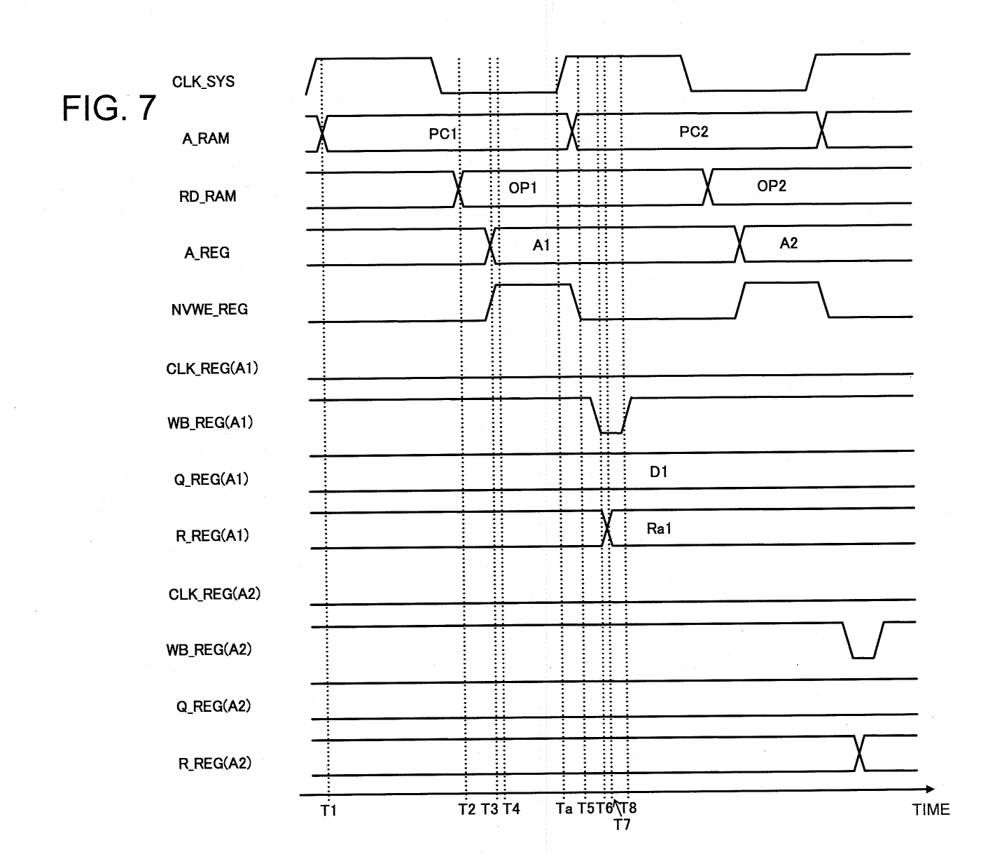

FIG. 7 shows example operation waveforms for a case the command code is a write command for writing into the non-volatile elements.

At a time T1, a central processing unit in the semiconductor integrated circuit 1 outputs PC1, a value of a program counter PC, to the memory 40 by way of an address A_RAM.

At a time T2, the central processing unit receives, from the memory 40, a command OP1, by way of data RD_RAM corresponding to the address A_RAM. It is noted that the command OP1 is of the command style shown in FIG. 3 and the command code is a write command code for writing into the non-volatile elements. It is also noted that the addressing mode is of the single operand style and specifies a register of the address A1.

At a time T3, the command decoder 50 of the central processing unit decodes the command OP1 to output the address A1 as the address A_REG of the register.

At a time T4, the command decoder 50 decodes the command OP1 and outputs the write signal NVWE_REG for the non-volatile elements to the non-volatile register control circuit 30. The outputting comes to a close at a time T5.

During the time since T6 until T8, the non-volatile register control circuit 30 sets the write signal WB_REG (A1) for the register of the address A1 selected to the L level to cause the current to flow in the non-volatile register R1.

At a time T7, the value of the non-volatile elements in the non-volatile register R1 corresponding to the address A1 is rewritten to a value Ral (resistance value R_REG(A1)) corresponding to the data output Q_REG(A1) retained.

During the next clock cycle, the write operation for the non-volatile elements in the non-volatile register R2 corresponding to the address A2 occurs, and the corresponding waveform is shown. The write operation occurs by a sequence of operations which is the same as that for the address A1. It is noted that, as shown in FIG. 7, the time period since T6 until T8, within which the write operation occurs for the non-volatile elements, may temporally be later than a time Ta when the cycle to read out the next command from the memory 40 commences. It is because the write operation into the non-volatile elements may be done without changing the output of the non-volatile register and hence is not deterrent to the operation of reading out the next command. By using such pipelining-like operation, it is possible to assure sufficient setup time for writing into the non-volatile elements as well as to execute a plurality of commands within a short time.

Next, such a case in which, in the semiconductor integrated circuit 1, the command code is a load command for the non-volatile elements, will be considered in depth.

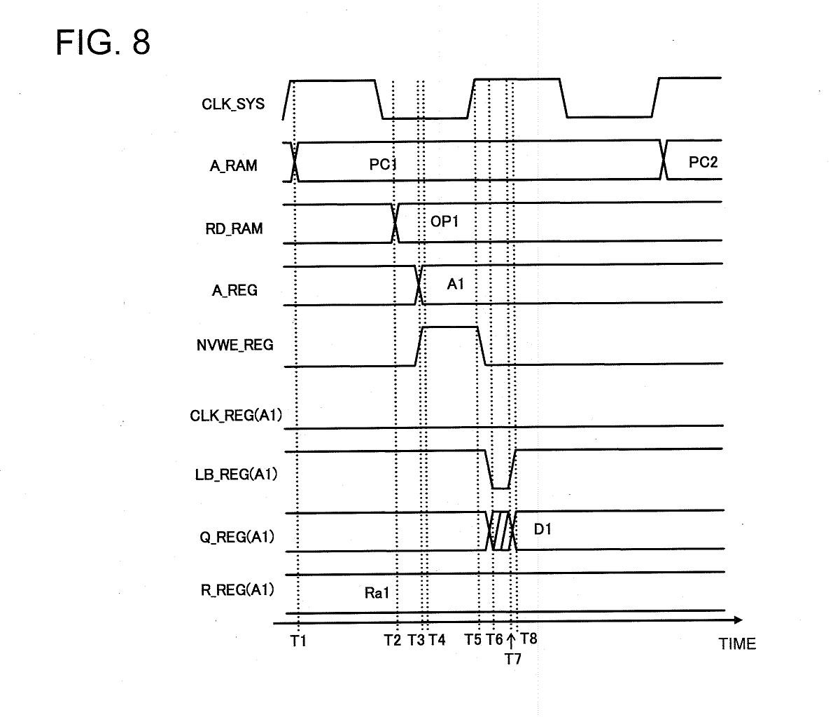

FIG. 8 shows example operation waveforms in case the command code is a load command for the non-volatile elements.

At a time T1, the central processing unit in the semiconductor integrated circuit 1 outputs PC1, a value of a program counter PC, to the memory 40 by way of an address A_RAM.

At a time T2, the central processing unit receives, from the memory 40, a command OP1, by way of data RD_RAM corresponding to the address A_RAM. It is noted that the command OP1 is of the command style shown in FIG. 3 and the command code is the code of the write command for the non-volatile elements. It is also noted that the addressing mode is of the single operand style and specifies a register of the address A1.

Such an operation will now be considered in which the load enable bit LEB corresponding to the address A1 has already been loaded, its bit value is ‘1’ and loading is made for the non-volatile register R1 corresponding to the address A1.

At a time T3, the command decoder 50 decodes the command OP1 to output the address A1 as the address A_REG of the register.

At a time T4, the command decoder 50 decodes the command OP1 to output a load signal NVLE_REG for the non-volatile elements to the non-volatile register control circuit 30. The outputting comes to a close at a time T5.

During the time since T6 until T7, the non-volatile register control circuit 30 sets the load signal LB_REG (A1) for the register of the address A1 selected to the L level to effect the loading for the non-volatile register.

At a time T8, the data output Q_REG(A1) of the non-volatile register R1 corresponding to the address A1 is rewritten to a value D1 corresponding to the value Ral retained by the non-volatile elements (resistance value R_REG(A1)).

As described above, the semiconductor integrated circuit 1 according to the subject exemplary embodiment includes the non-volatile register in which the logic element and the non-volatile element are integrated together. Thus, in restoration of the supply power of the semiconductor integrated circuit 1, it is possible to reduce the time and power consumption involved in restoring the retreated data. Moreover, loading may be made for just the targeted register(s) by exploiting the load enable bit(s) LEB. This renders it possible to reduce the number of the non-volatile elements from which loading is made, thus allowing reducing the power consumption involved in the loading.

### Exemplary Embodiment 2

An exemplary embodiment 2 will now be described in detail with reference to the drawings.

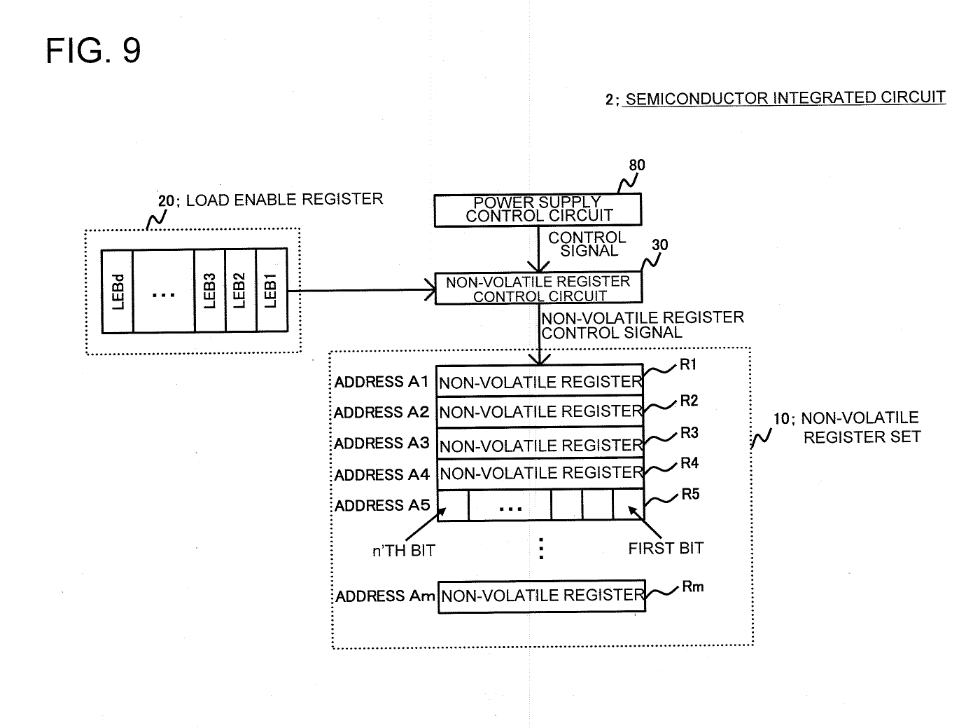

FIG. 9 shows an example interior configuration of a semiconductor integrated circuit 2 according to the subject exemplary embodiment. In FIG. 9, the same symbols are used to depict parts or components which are the same as those shown in FIG. 2 and the corresponding description is dispensed with. The semiconductor integrated circuit 2 differs from the semiconductor integrated circuit 1 in that a power supply control circuit 80 is used to deliver a control signal without using the memory 40 as well as the command decoder 50.

In the semiconductor integrated circuit 2 according to the subject exemplary embodiment, the non-volatile registers are controlled not by a program (software) recorded in the memory 40 as in the semiconductor integrated circuit 1. In the semiconductor integrated circuit 2, in which the non-volatile registers are controlled by hardware, such as a power supply control circuit 80, power consumption may similarly be suppressed through the use of the load enable bits LEB.

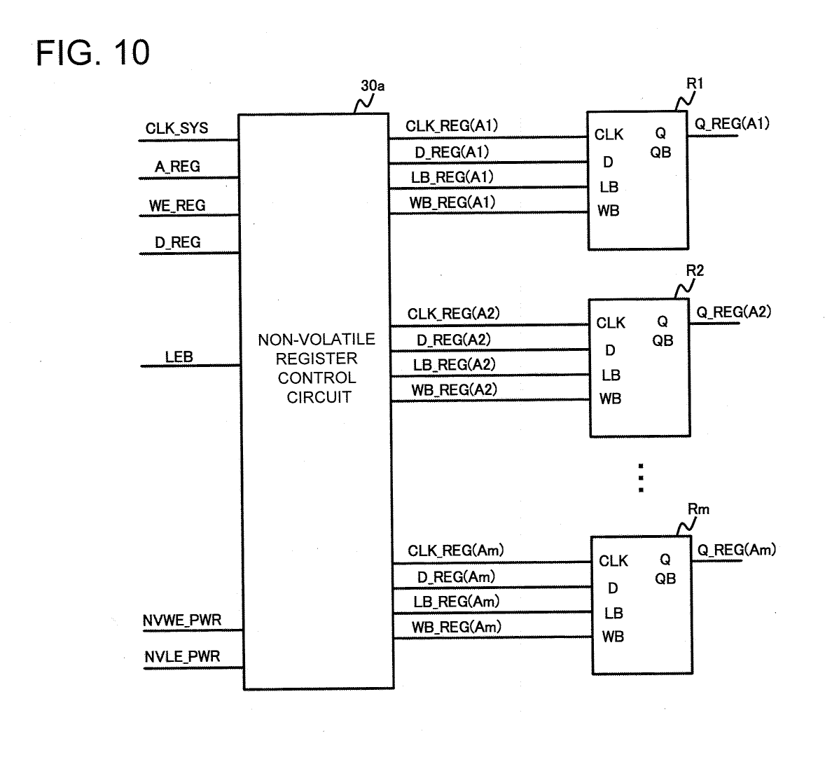

FIG. 10 shows example connections of non-volatile registers R1 to Rm to a non-volatile register control circuit 30a, all included in the semiconductor integrated circuit 2. The non-volatile register control circuit is a control circuit for the non-volatile registers. In FIG. 10, the same symbols are used to depict the same parts or components as those used in FIG. 6 and the corresponding explanation is dispensed with. FIG. 10 differs from FIG. 6 in that both the write signal NVWE_REG, sent from the control decoder 50, and the load signal NVLE_REG from the non-volatile elements, are deleted, and a write signal NVWE_PWR sent from the power supply control circuit 80 as well as a load signal NVLE_PWR from the non-volatile elements are added.

The m non-volatile registers are divided into q groups G1 to Gq. Each group is either correlated to one of the plural load enable bits LEB1 through to LEBd, in a one-for-one relationship, or correlated to none of the load enable bits.

The load enable bits LEB are loaded into the non-volatile register control circuit 30 immediately after supply power is delivered to the semiconductor integrated circuit 2. That is, the load enable bits LEB are loaded into the non-volatile register control circuit 30 before loading occurs in the non-volatile registers R1 to Rm. Thus, the non-volatile register control circuit 30a is able to refer to the load enable bits LEB in advance of the non-volatile registers R1 to Rm.

Additionally, the m non-volatile registers are divided into t groups G1 to Gt. Furthermore, the non-volatile register control circuit 30a is able to receives load signals NVLE_PWR1 to NVLE_PWRs, where s is an integer not smaller than 2, hereinafter the same. Each non-volatile register group is either correlated in a one-for-one correspondence to one NVLE_PWR out of the load signals NVLE_PWR1 to NVLE_PWRs or lacking in the correlated load signal NVLE_PWR.

After recovery of the supply power, the non-volatile register control circuit 30a specifies the total of the non-volatile registers, belonging to the group corresponding to the activated load signal, based on the s load signals NVLE_PWR delivered from the power supply control circuit 80. The non-volatile register control circuit 30a refers to the load enable bit LEB of the group of the so specified non-volatile registers. If the value of the load enable bit LEB, thus referred to, is ‘1’, the non-volatile register control circuit 30a causes data of the non-volatile elements in the specified non-volatile registers to be loaded in the retention circuits. If the value of the load enable bit LEB, thus referred to, is ‘0’, data of the non-volatile elements in the specified non-volatile registers is not loaded in the retention circuits. For a case where there is no corresponding load enable bit LEB, whether or not data of the non-volatile elements in the specified non-volatile register is to be loaded is fixedly set in advance in the non-volatile register control circuit 30a.

In writing, the m non-volatile registers are similarly divided into t groups G1 to Gt. Also, the non-volatile register control circuit 30a receives s write signals NVWE_PWR1 to NVWE_PWRs. Each non-volatile register group is either correlated in one-for-one correspondence to one write signal NVWE_PWR out of the write signals NVWE_PWR1 to NVWE_PWRs or correlated to none of the write signals.

Before the supply power, so far delivered to the semiconductor integrated circuit 2, is turned off, the non-volatile register control circuit 30a specifies, based on the s write signals NVWE_PWR received from the power supply control circuit 80, the total of the non-volatile registers belonging to the group corresponding to the write signal NVWE_PWR activated. Data of the retention circuits, contained in the non-volatile registers specified, are written in the non-volatile elements.

In the semiconductor integrated circuit 2, the non-volatile registers R1 to Rm do not necessarily have to be correlated to the addresses, because write or readout signals are given in terms of a group(s) as unit, as stated above.

In the semiconductor integrated circuit 2 of the subject exemplary embodiment, it is again possible to suppress power consumption as well as time involved in restoring data from the once-retreated state at the time of restoration of the power supply. Moreover, since control is exercised by the power supply control circuit 80, as hardware, instead of by the central processing unit (program), the time delay caused by command fetch from the memory 40 as well as the power consumption may be reduced more effectively.

Moreover, since program control is not used, the storage space in the memory 40, that is, the program size, may be decreased.

### Exemplary embodiment 3

Next, an exemplary embodiment 3 will now be described in detail with reference to the drawings.

A semiconductor integrated circuit 3 according to the subject exemplary embodiment differs from the semiconductor integrated circuit 1 as to the operation performed at the system boot or start time. Hence, the explanation of the semiconductor integrated circuit 3 relevant to FIG. 2 to 6 is dispensed with.

The semiconductor integrated circuit 3 uses a loading-related branch flag. The loading-related branch flag is used for selecting the operation mode at the time of system restoration. Additionally, the loading-related branch flag is retained by the non-volatile register and corresponding data is written in the non-volatile elements in advance of power supply interruption. It is noted that the non-volatile register, retaining the loading-related branch flag, can be controlled by the non-volatile register control circuit 30, in the same way as the other non-volatile registers.

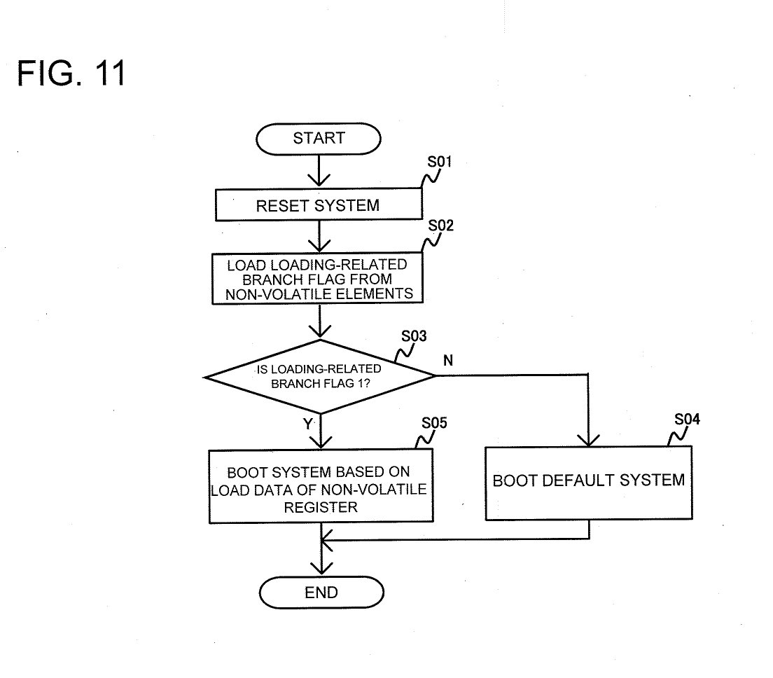

FIG. 11 depicts a flowchart showing an example operation of the semiconductor integrated circuit 3 at the system boot or start time.

In a step S01, a system is reset before supply power is delivered to the system.

In a step S02, data corresponding to the loading-related branch flag is loaded in the non-volatile register that is to retain the loading-related branch flag.

In a step S03, it is verified whether or not the loading-related branch flag is ‘1’. If the loading-related branch flag is ‘0’, processing transfers to a step S04 and, if the loading-related branch flag is ‘1’, processing transfers to a step S05.

In the step S04, a default system boot, not including the load operation in the non-volatile registers, is performed.

In the step S05, a system boot, including the load operation in the non-volatile registers, is performed.

For the above mentioned system boot, including the non-volatile register load operation, address naming by the load enable bit(s) LEB or by the command code, as disclosed in the exemplary embodiment 1, may be used. This enables loading just for the targeted register(s).

It is noted that power supply may be turned onRmoff not only for the semiconductor integrated circuit 3 in its entirety but just for one or more of a plurality of modules that make up the semiconductor integrated circuit 3. If the power supply is turned onRmoff on the module basis, resetting following re-start of power supply to the module in question may be performed only for such module.

As stated above, the semiconductor integrated circuit 3 of the subject exemplary embodiment includes the non-volatile register in which the logic device and the non-volatile register elements are integrated together. It is thus possible to decrease time and power consumption involved in restoring once-retreated data at the time of re-start of power supply to the semiconductor integrated circuit 3.

Moreover, when turning on the power supply, it is not strictly necessary to restore the state that prevailed before turning off of the power supply, such that an as-intended state may be realized at once more flexibly. In addition, since the loading-related branch flag is retained in the non-volatile register, it is unnecessary to transfer the loading-related branch flag from the memory 40 in distinction from such case in which the loading-related branch flag is stored in the memory 40. It is thus possible to reduce power consumption and time delay caused in the data transfer as well as to simplify the control (procedure) in exploiting the loading-related branch flag.

Furthermore, by exploiting the load enable bit (LEB) or the load command as well, it becomes possible to load just difference data between the as-intended system state and the as-reset system state, and hence to reduce the power consumption involved in loading from the non-volatile elements.

### Exemplary embodiment 4

Next, an exemplary embodiment 4 will now be described in detail with reference to the drawings.

A semiconductor integrated circuit 4 according to the subject exemplary embodiment differs from the semiconductor integrated circuit 1 as to the operation at the system boot time. Hence, the explanation of the semiconductor integrated circuit 4 relevant to FIG. 2 to 6 is dispensed with.

A non-volatile register of the semiconductor integrated circuit 4 retains data of a program counter PC. The data of the program counter PC represent the address information for the command that is stored in a memory 40 so as to be executed next time. Before the power supply for the semiconductor integrated circuit 4 is turned off, the semiconductor integrated circuit 4 causes the value of the program counter PC, from which the operation is desired to be started at the time of the next restoration, to be written in the non-volatile elements.

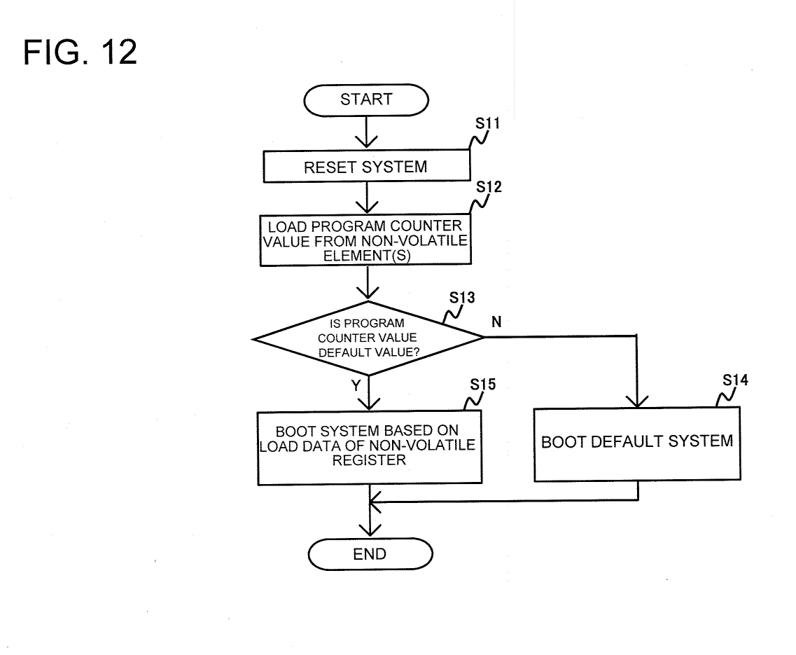

FIG. 12 depicts a flowchart showing an example operation at the system boot time of the semiconductor integrated circuit 4.

In a step S11, the system is reset before delivery of the supply power.

In a step S12, in the non-volatile register, retaining the value of the program counter PC, the data of the program counter PC, stored in the non-volatile register, is loaded into its retention circuit.

In a step S13, it is verified whether or not the value of the program counter PC loaded is a default value. If such value is a default value, processing transfers to a step S14. If otherwise, processing transfers to a step S15.

In the step S14, a default system boot, not including a load operation for the non-volatile register(s), is made.

In the step S15, a system boot, including the load operation for the non-volatile register(s), is made. At such time, an address is named (identified) by the load enable bit LEB or by the command code as explained in the exemplary embodiment 1. This renders it possible to effect the loading just for the targeted register.

While the explanation in the subject exemplary embodiment has been made for the case of using load enable bits, it is not strictly necessary to use the load enable bits. In addition, power supply may be turned onRmoff not only for the semiconductor integrated circuit 4 in its entirety but just for one or more of a plurality of modules that make up the semiconductor integrated circuit 4. If the power supply is turned onRmoff on the module basis, resetting following re-start of power supply to the module in question may be performed only for such module.

In the semiconductor integrated circuit 4 of the subject exemplary embodiment, the load enable bit (LEB) or the load command may be exploited in combination to render it possible to load just difference data between the as-intended system state and the as-reset system state, and hence to reduce the power consumption involved in loading from the non-volatile elements.

### Exemplary embodiment 5

Next, an exemplary embodiment 5 will now be described in detail with reference to the drawings.

The semiconductor integrated circuit 4, shown in the exemplary embodiment 4, is such one in which value of the program counter PC is stored in the non-volatile register. In the subject exemplary embodiment, such matter that has to be taken into consideration in writing the value of the PC counter PC in the non-volatile elements will be scrutinized.

In the non-volatile flipflop 60, discussed with reference to FIG. 4, data of the slave latch 62 can be written in the non-volatile elements 63, 64. If, in such case, the value of the program counter PC, at which the operation is desired to be commenced on restoration from the power supply interruption, is the same as the value stored in the slave latch 62, no particular problem arises. However, there arises a problem in case the value of the program counter PC, from which the operation on the next restoration is desired to be commenced, differs from the value stored in the slave latch 62. That is, if the address for the time of the next restoration is written in the non-volatile elements 63, 64, the value retained by the slave latch 62 is updated. At this time, the address actually accessed is not the address to be accessed at the next cycle, but the address from which it is desired to start the operation after power supply restoration.

To solve such problem, it may be contemplated to add to the non-volatile flipflop 60 some suitable expedient which will enable data of the non-volatile elements to be directly written without updating data of the slave latch 62. A semiconductor integrated circuit 5 according to the subject exemplary embodiment includes a non-volatile flipflop 60a in which such expedient has been used.

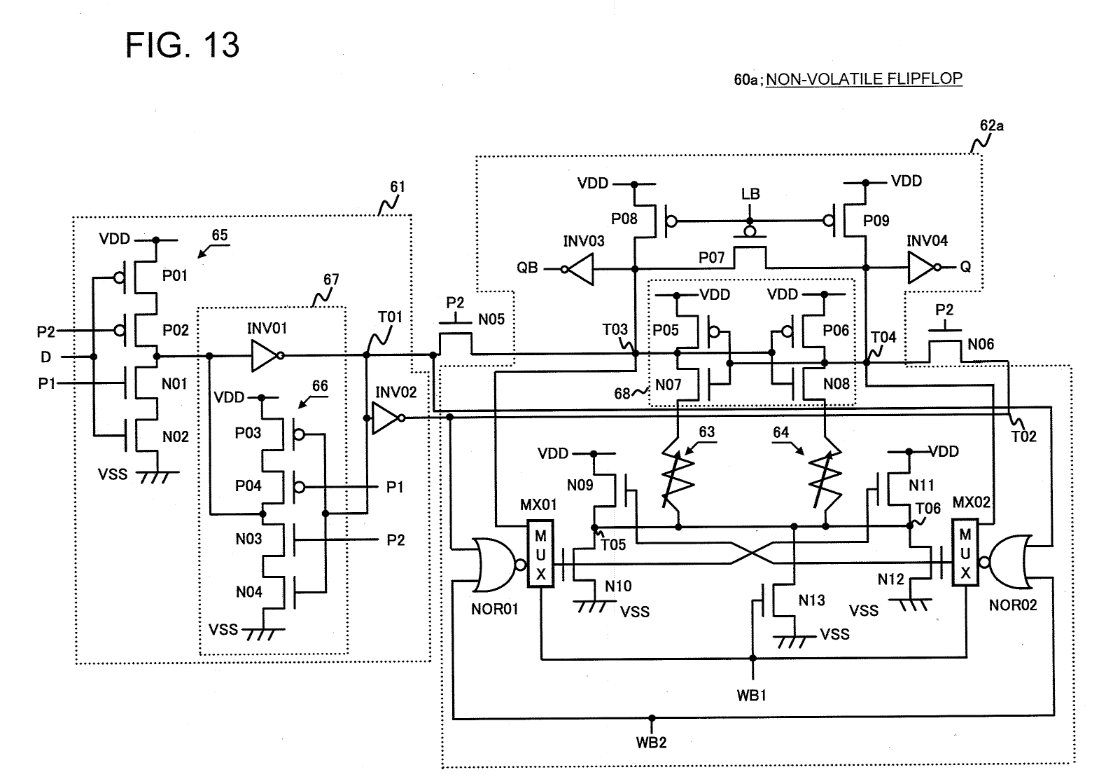

FIG. 13 shows an example circuit configuration of the non-volatile flipflop 60a. In FIG. 13, those components that are the same as those shown in FIG. 4 are denoted by the same symbols and the corresponding description is dispensed with. The non-volatile flipflop 60a differs from the non-volatile flipflop 60 as to a peripheral circuit that controls the N-channel MOS transistors N09 to N12 which are write transistors.

Specifically, multiplexers MUX01, MUX02 are added to enable either data of a slave latch 62a or input data D to be selected as data for writing in accordance with write signals WB1, WB2.

The non-volatile flipflop 60a receives two write signals WB1, WB2 and one input data D. In case the write signal WB1 is activated, data of the retention circuit 68 is written in the non-volatile elements 63, 64. In case the write signal WB2 is activated, the input data D is written in the non-volatile elements 63, 64, while data of the retention circuit 68 is not changed. In writing the input data D into the non-volatile elements 63, 64, the clock CLK is set to the L level. By so doing, the input data D may be written into the non-volatile elements 63, 64 without changing data of the slave latch 62a.

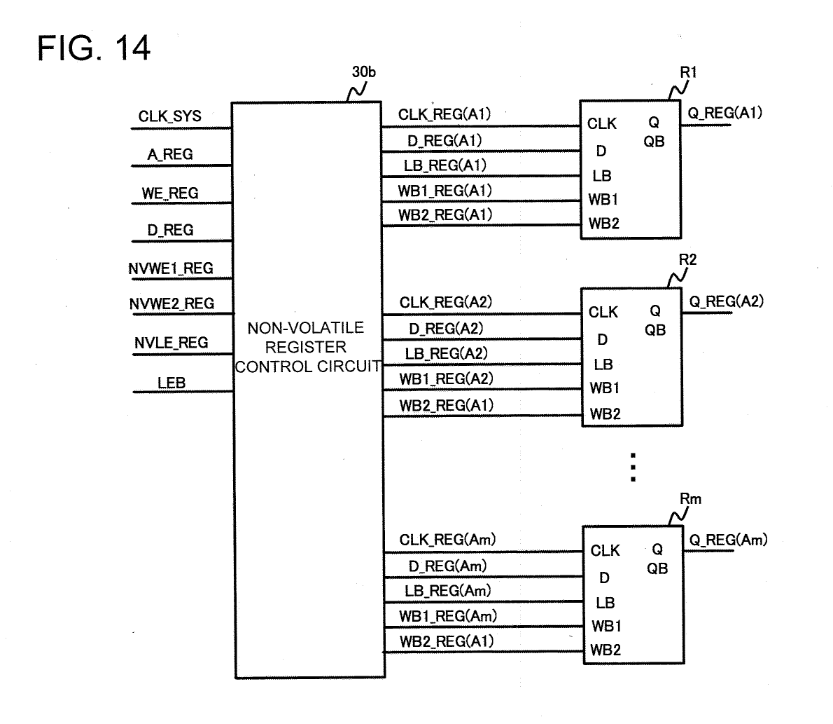

FIG. 14 shows example connections of non-volatile registers R1 to Rm to the non-volatile register control circuit 30b which is a control circuit for the non-volatile registers. All of these are contained in the semiconductor integrated circuit 5. FIG. 14 differs from FIG. 6 in that the non-volatile register control circuit 30b receives two non-volatile element write signals NVWE1_REG and NVWE2_REG. Also, the non-volatile register control circuit 30b outputs two non-volatile element write signals WB1_REG(A1) and WB2_REG(A1) to the non-volatile register R1 corresponding to the address A1. The same may be said of the non-volatile registers R2 to Rm corresponding respectively to the addresses A2 to Am.

In the semiconductor integrated circuit 5, in case the non-volatile element write signal NVWE1_REG is activated, data of the slave latch of the non-volatile register selected may be written in the non-volatile elements. On the other hand, in case the non-volatile element write signal NVWE2_REG is activated, the input data D_REG may be written in the non-volatile elements. With the non-volatile flipflop 60a, shown in FIG. 13, it is possible to select one of two data to write either data. However, as may be seen on comparing FIG. 13 to FIG. 6, no interconnection for write data is added, and hence the overhead for the space occupied by the interconnection may be suppressed from increasing.

In FIG. 14, the non-volatile flipflops are assumed in their entirety to be the non-volatile flipflops 60a. Alternatively, however, the non-volatile flipflops 60, explained in connection with the exemplary embodiment 1, may be used in conjunction with the non-volatile flipflops 60a in certain proportions to each other.

Moreover, the flipflops 60a of the subject exemplary embodiment may be used in conjunction not only with the program counter PC but also with such registers which are desirably not changed by the slave latch data.

As stated above, the semiconductor integrated circuit 5 of the subject exemplary embodiment includes non-volatile registers in each of which the logic element and the non-volatile elements are integrated together. Thus, in restoring the power supply of the semiconductor integrated circuit 5, it is possible to suppress power consumption as well as time involved in restoring the retreated data.

Additionally, data for the retention circuit and for the non-volatile elements of the non-volatile flipflops 60a may be written independently of each other. Hence, the value of the program counter PC at which it is desired to restart the operation on restoration from the state of power supply interruption, or the values of the other non-volatile resisters, may be written in the non-volatile elements without changing the inner system states stored in the retention circuit. It is thus possible to restore the targeted state more flexibly.

The disclosures of the above recited Patent Literatures are to be incorporated herein by reference. The particular exemplary embodiments or examples may be modified or adjusted within the gamut of the entire disclosure of the present invention, inclusive of claims, based on the fundamental technical concept of the invention. Moreover, a variety of combinations or selection of elements herein disclosed (elements the claims, exemplary embodiments, examples or drawings) may be made within the concept of the claims. Also, the present invention may include a variety of changes or corrections that may occur to those skilled in the art in accordance with the total disclosures inclusive of the claims and the drawings as well as the technical concept of the invention. For example, while the above detailed explanation, which has been centered about the registers within the central processing unit, may be extended with ease to the registers within the peripheral modules. Also, while it is presumed in each of the exemplary embodiments that an address is donated to each register, it should be possible to write to or read out from the non-volatile elements of those registers to which no addresses are donated. That is, even if the data of the retention circuit may not be directly written or read out from the program because no addresses are donated to the data, the data may be made to belong to one of the groups of the non-volatile elements so that the non-volatile elements may still be written or read out. Also, the range of numerical values stated herein should be interpreted to be inclusive of optional numerical values or sub-ranges contained within the range even if no explicit statement is made of the values or sub-ranges.

### REFERENCE SIGNS LIST

1˜5, 100 semiconductor integrated circuits
10 non-volatile register set
20 load enable register
30, 30a, 30b, 105 non-volatile register control circuits
40 memory
50 command decoder
60, 60a non-volatile flipflops
61 master latch
62, 62a slave latches
63, 64, 102 non-volatile elements
65, 66 clocked inverters
67, 68, 101 retention circuits
70 metal layer
71 first hard layer
72 second hard layer
73 free layer
74 insulation layer
75 reference layer
80 power supply control circuit
103 first non-volatile register
104 second non-volatile register

1. A semiconductor integrated circuit, comprising:
a plurality of first non-volatile registers including a retention circuit that retains volatile data and a non-volatile element(s) capable of retaining non-volatile data;
a second non-volatile register that retains a load enable bit that decides in which one of the plurality of first non-volatile registers data is loaded; and
a non-volatile register control circuit that causes the data retained by the non-volatile element(s) contained in the first non-volatile register identified by the load enable bit loaded from the second non-volatile register to be loaded into the retention circuit, when supply power is delivered from outside.

2. The semiconductor integrated circuit according to claim 1, wherein,
the plurality of first non-volatile registers are divided into a plurality of groups, each group being either correlated or not correlated to the load enable bit;
the non-volatile register control circuit causing the data retained by the non-volatile element(s) contained in the first non-volatile register belonging to the group specified by the load enable bit to be loaded in the retention circuit.

3. The semiconductor integrated circuit according to claim 2, wherein, whether or not data retained by the non-volatile element(s) contained in the first non-volatile register belonging to the group not correlated to the load enable bit is to be loaded into the retention circuit is to obey a predetermined rule.

4. The semiconductor integrated circuit according to claim 1, further comprising
a command decoder that decodes a command issued to a central processing unit; and
a memory that retains the command;
each of the plurality of first non-volatile registers having an address donated thereto; the first non-volatile registers being divided into a plurality of groups;
the command including an address bit that specifies an address corresponding to the plurality of first non-volatile registers and a load bit that instructs loading data in the plurality of first non-volatile registers;
the non-volatile register control circuit as a result of the command decoder decoding the command read out from the memory causing loading of data in the first non-volatile register(s), which belong to the same group of the first non-volatile registers as that of the first non-volatile register identified by the address bit, and for which the corresponding load bit has been activated.

5. The semiconductor integrated circuit according to claim 1, wherein,
the plurality of first non-volatile registers are divided into a plurality of groups;
the semiconductor integrated circuit comprising a power supply control circuit capable of delivering a plurality of load signals that decide which of the groups the plurality of first non-volatile registers belong to is to be activated;
the non-volatile register control circuit causing loading of data in the first non-volatile registers which belong to the group corresponding to the load signal delivered by the power supply control circuit and for which the corresponding load enable bit has been activated.

6. The semiconductor integrated circuit according to claim 1, wherein,
the non-volatile register control circuit performs, based on a loading-related branch flag, when supply power is delivered from outside, either a system boot not including the operation of loading to the retention circuit the data retained by the non-volatile element(s) included in the first non-volatile register or a system boot including the operation of loading to the retention circuit the data retained by the non-volatile element(s) included in the first non-volatile register.

7. The semiconductor integrated circuit according to claim 1, wherein,
data relevant to a program counter is retained by one of the plurality of first non-volatile registers;
the non-volatile register control circuit when supply power is delivered from outside causing data to be loaded to the retention circuit from the non-volatile element(s) contained in the non-volatile register that retains the program counter;
the non-volatile register control circuit performing, based on a value of the program counter, either a system boot not including the operation of loading to the retention circuit the data retained by the non-volatile element(s) included in the first non-volatile register, or a system boot including the operation of loading to the retention circuit the data retained by the non-volatile element(s) included in the first non-volatile register.

8. The semiconductor integrated circuit according to claim 1, wherein,
the plurality of non-volatile registers receive first and second write signals and one input data;
the non-volatile registers in case of activation of the first write signal allowing the data of the retention circuit to be written into the non-volatile elements;
the non-volatile registers in case of activation of the second write signal allowing the input data to be written in the non-volatile element(s) without changing data retained by the retention circuit.

9. A method for controlling a semiconductor integrated circuit including a plurality of first non-volatile registers comprising a retention circuit that retains volatile data and a non-volatile element(s) capable of retaining non-volatile data; the method comprising:
referring to a load enable bit that decides in which of the plural first non-volatile registers the data is to be loaded; and
loading the data retained by the non-volatile element(s) contained in the first non-volatile register identified by the load enable bit into the retention circuit when supply power is delivered from outside.

10. The method for controlling a semiconductor integrated circuit according to claim 9, wherein,
said loading the data retained by the non-volatile element(s) includes either booting a system as the data retained by the non-volatile element(s) contained in the first non-volatile register is not loaded into the retention circuit, or booting the system as the data retained by the non-volatile element(s) contained in the first non-volatile register is loaded into the retention circuit, based on a loading-related branch flag, when the supply power is delivered from outside.
